(19) United States
(12) Patent Application Publication
(10) Pub. No.: US 2014/0224676 A1
(43) Pub. Date: Aug. 14, 2014

(54) LOW PROFILE PROTECTIVE COVER CONFIGURABLE AS A STAND WITH INTEGRATED BATTERY

(71) Applicant: M-EDGE ACCESSORIES, LLC, Odenton, MD (US)

(72) Inventors: Adam Ryan Ashley, Odenton, MD (US); Patrick Mish, Odenton, MD (US); James Ward, Ashburn, VA (US); Christopher Richard Helman, Linthicum, MD (US); Jonathan David McCune, Stephensville, MD (US)

(73) Assignee: M-EDGE ACCESSORIES, LLC, Odenton, MD (US)

(21) Appl. No.: 14/255,187

(22) Filed: Apr. 17, 2014

Related U.S. Application Data
(63) Continuation-in-part of application No. 13/759,494, filed on Feb. 5, 2013.

(51) Int. Cl. H05K 5/03

(52) U.S. Cl. CPC H05K 5/03
USPC 206/37

(57) ABSTRACT

A protective cover having a front cover, a rear cover including a middle rear cover, an exterior rear cover, and a folding portion that connects the middle rear cover to the exterior rear cover, an articulable back that connects the rear cover to the front cover, a holding member that is attached to an inner surface of the exterior rear cover and not attached to the middle rear cover for securing the electronic device to the protective cover, and a battery attached to the middle rear cover.

### CROSS-REFERENCE TO RELATED APPLICATIONS

This is a continuation-in-part application of copending U.S. patent application Ser. No. 13/759,494, filed on Feb. 5, 2013, which is incorporated by reference herein in its entirety.

### FIELD OF THE INVENTION

The present invention relates generally to a protective casing or cover for an electronic device having a display, the protective casing or cover having a very low profile that can be unfolded to be configured as a stand for the electronic device.

### BACKGROUND OF THE INVENTION

Various types of electronic devices are currently available for a variety of different purposes, such as communications, business, entertainment, having a tablet bar shape with a display screen covering a large part of the front face of the electronic device, and are not the traditional foldable devices like the conventional laptop or notebook design. Because these electronic devices are mobile and are often carried around by the user, protective covers have been designed to protect the electronic device from scratches, impacts, dust, water, but also for aesthetic purposes for example made of leather. However, conventional protective covers usually require multiple parts that protrude from a back cover sheet of the protective cover, making the protective cover design thick and bulky. Also, usually protective covers use plastic clips or holders to attach an electronic device, and these clips or holders can break after some time of usage, so that the protective cover needs to be replaced. In addition, many conventional protective covers use many additional components to use the protective cover as a stand, for example a leg that is attached on an outer surface of casing so that the protective cover can serve to hold the display screen at a certain angle towards the user. Furthermore, conventional covers do not provide a source of power to charge the electronic device that is integrated with the cover. Accordingly, despite the existing solutions for protective covers, there is still a need for improved and simplified designs of protective covers.

### SUMMARY OF THE EMBODIMENTS OF THE INVENTION

According to one aspect of the present invention, a protective cover is provided. The protective cover includes a front cover, a rear cover including a middle rear cover, an exterior rear cover, and a folding portion that connects the middle rear cover to the exterior rear cover. The protective cover further includes an articulable hack that connects the rear cover to the front cover, a holding member that is attached to an inner surface of the exterior rear cover and is not attached to the middle rear cover for securing the electronic device to the protective cover. The protective cover also includes a battery that is attached to the middle rear cover.

The summary of the invention is neither intended nor should it be construed as being representative of the full extent and the scope of the invention, which additional aspects will become more readily apparent from the detailed description, particularly when taken together with the appended drawings.

### BRIEF DESCRIPTION OF THE SEVERAL VIEWS OF THE DRAWINGS

The accompanying drawings, which are incorporated herein and constitute part of this specification, illustrate the presently preferred embodiments of the invention, and together with the general description given above and the detailed description given below, serve to explain features of the invention.

FIG. 1 shows a plan view of a protective cover in an open state including an electronic device;

FIG. 2 shows a plan view of a protective cover in an open state with the electronic device removed;

FIG. 3 shows a perspective view of the protective cover having angled rear cover sheet;

FIG. 4 shows a perspective view of the protective cover with the electronic device attached thereto in an opened state;

FIG. 5 shows a perspective view of the protective cover in a first open position with the electronic device attached thereto;

FIG. 6 shows a perspective view of the protective cover in a second open position with the electronic device attached thereto;

FIG. 7 shows a profile view of the protective cover in an open state;

FIG. 8 shows a perspective view of the protective cover including an electronic device in a closed state;

FIG. 9 shows a plan view of another embodiment of the protective cover in an open state without an electronic device with an integrated keyboard;

FIG. 10A shows a plan view of another embodiment of the holding sheet for the protective cover;

FIG. 10B is a cross-sectional view of the holding sheet along the line 10B-10B indicated in FIG. 10A;

FIG. 11 shows a perspective view of another embodiment of a protective cover in an open state including an electronic device;

FIG. 12 shows a plan view of the protective cover in an open state including an electronic device;

FIG. 13 shows a perspective view of the protective cover in an open state including an electronic device;

FIG. 14 shows a perspective view of the protective cover in an open state with the electronic device removed and another embodiment of the holding sheet with an integrated battery;

FIG. 15 shows a perspective view of the protective cover in an open state with the electronic device removed and another embodiment of the holding sheet with an integrated. battery;

FIG. 16 shows a perspective view of another embodiment of a protective cover in an open state including an electronic device and an integrated battery; and

FIG. 17 shows a perspective view of the protective cover in an open state with the electronic device removed.

Herein, identical reference numerals are used, where possible, to designate identical elements that are common to the figures. Also, the images in the drawings are simplified for illustration purposes and may not be depicted to scale.

### DETAILED DESCRIPTION OF THE SEVERAL EMBODIMENTS

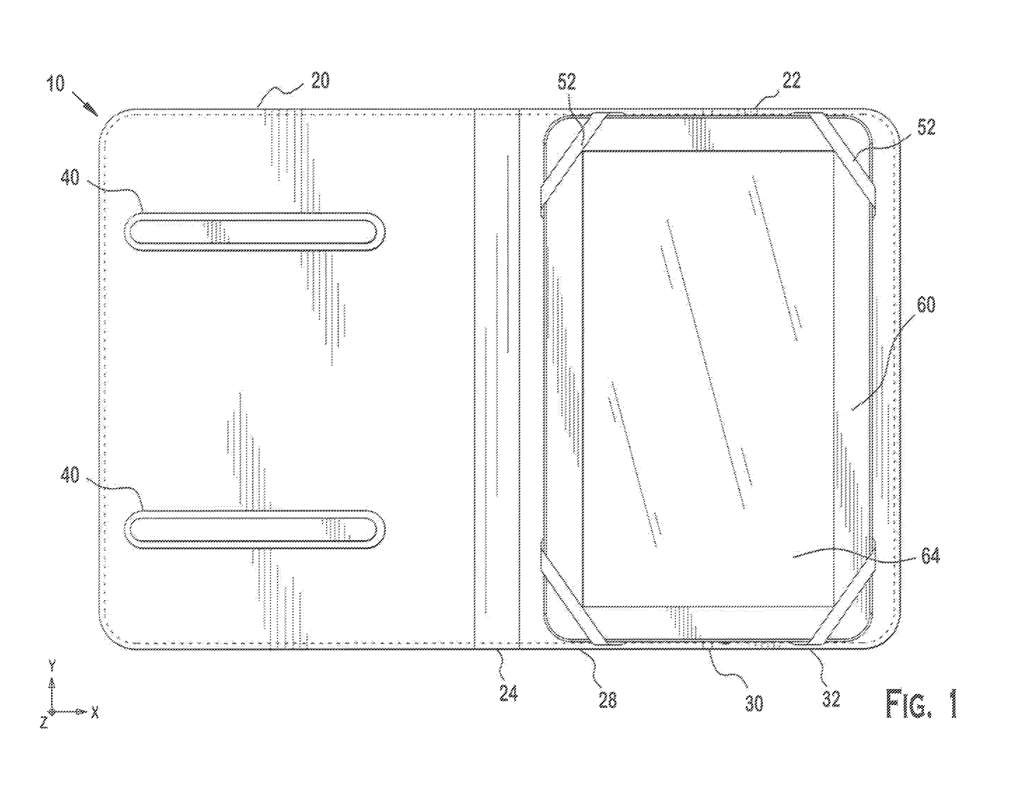

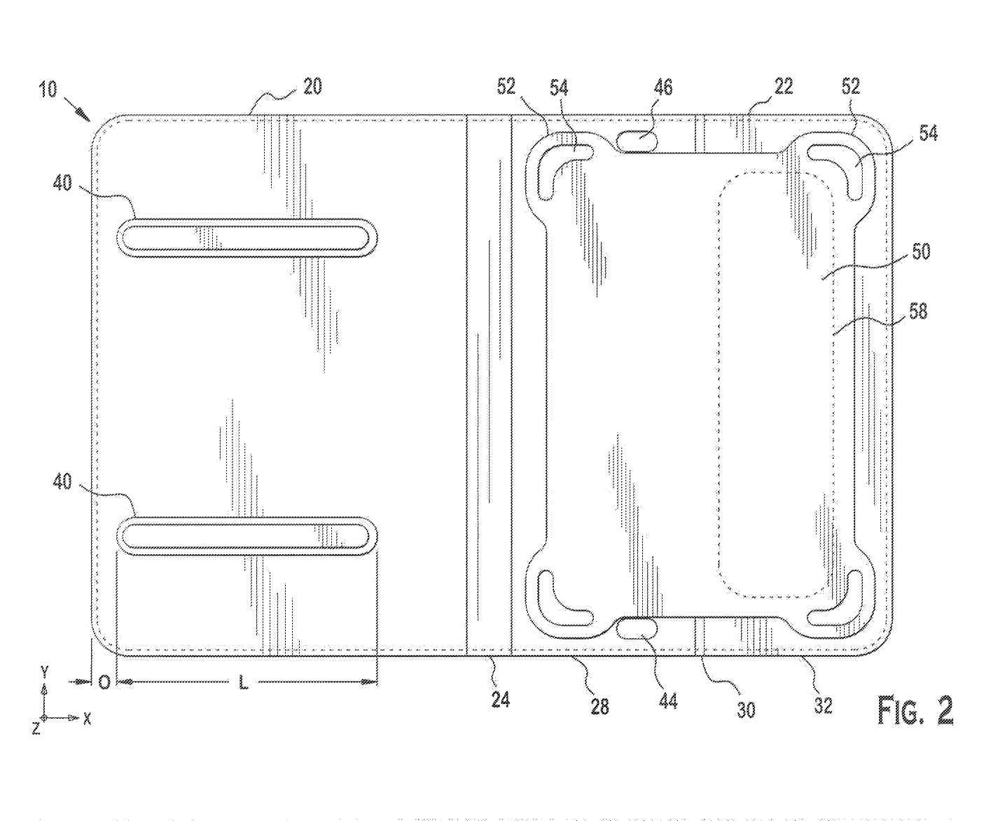

FIG. 1 shows a plan view of the protective cover 10 according to an embodiment of the present invention holding a computerized mobile electronic device 60 having a tablet shape, such as audio players, video players, portable digital video disk (DVD) players, cellular phones, smartphones, navigation devices, personal digital assistants, display units, e-book readers like Amazon Kindle™, tablet computers like Apple Ipad™, or Android-based tablets like Samsung GalaxyTab™, whereas FIG. 2 shows the same plan view of the protective cover 10 without the electronic device 60. For descriptive purposes, the description below makes references to an x, y, and z Cartesian coordinate system that is depicted in FIGS. 1, 2, and 3, in which the y-direction is defined by a longitudinal extension of cover 10, the x-direction is defined by the width extension of cover 10, and the z-direction is defined as being a direction that is perpendicular to the planar extension of cover 10 in an open position. In this respect, the negative x-direction is referred to as the left side, while the positive x-direction is referred to as the right side.

The protective cover 10 is made of a front cover sheet 20 that is attached via an articulable, pivotable, or foldable back portion 24, or spine portion, to a rear cover sheet 22. The articulable back portion 24 is arranged such that the front cover sheet 20 and rear cover sheet 22 can be folded relative to each other to close the protective cover 10 to contain electronic device 60. In a closed state, the inner surfaces of front cover sheet 20 and rear cover sheet 22 face each other and can sandwich an electronic device 60 between each other, the front cover sheet 20 and the rear cover sheet 22 arranged substantially parallel to each other. In an open state, the display 64 of electronic device 60 is exposed, and front cover sheet 20 can be opened at various angles towards rear cover sheet 22. At least one of the front cover sheet 20 and the rear cover sheet 22 can also be equipped with a mechanism (not shown) to hold front and rear cover sheet 20, 22 together in a closed state, for example but not limited to an elastic band, a hook and loop fastening strap, a zipper, magnetic strap, buckle, clip-on band, and push-button band laces. In addition, the rear cover sheet 22 is also configured to be foldable separately from the folding sheets 20, 22 relative to each other, and for this purpose rear cover sheet 22 is composed of a middle sheet 28 and an exterior sheet 32 that are connected to each other via folding member 30 (e.g., a hinge). In the embodiment shown, folding member 30 splits rear cover sheet 22 into two substantially equal sized parts, the middle sheet 28 and exterior sheet 32. Preferably, the folding member 30 may be positioned approximately ⅓ the width extension of the cover 10 measured. from the exterior edge of the cover 10. A holding sheet 50 that is configured to attach to electronic device 60 is attached to the exterior sheet 32 of rear cover sheet 22 by an attachment thread 58, but is not attached to middle sheet 28 of rear cover sheet 22. Holding, sheet 50 is configured such that it serves as a mounting bracket to hold electronic device 60 removably to protective cover 10, as further discussed below.

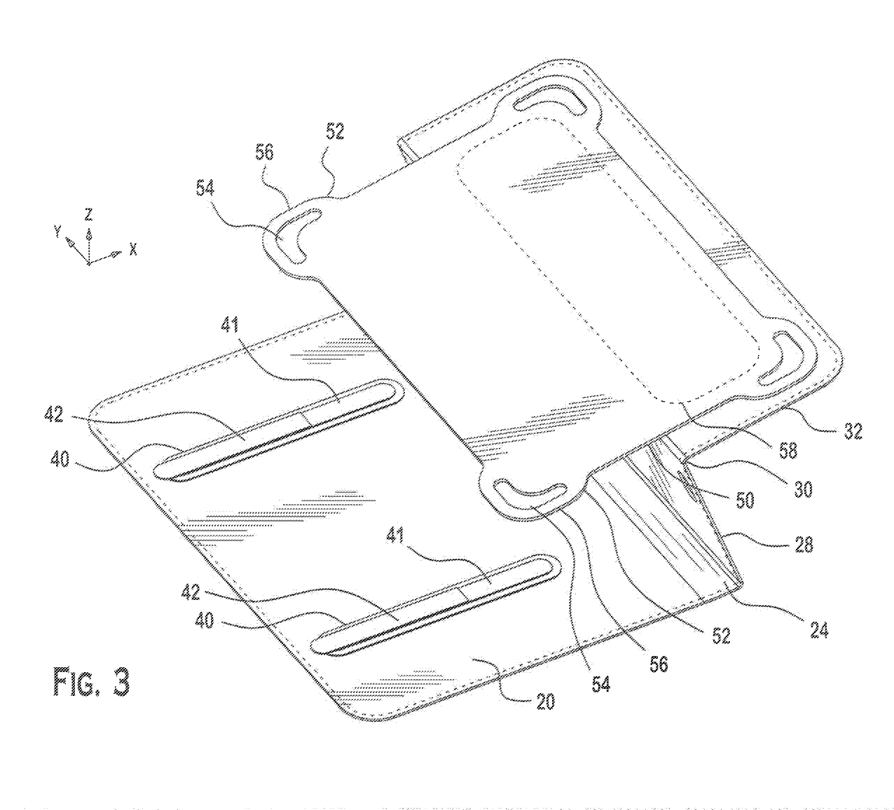

As shown in FIG. 3, folding member 30 is arranged in a way that rear cover sheet 2.2 can be bent such that the left side of holding sheet 50, the part of holding sheet 50 that is not attached to inner surface of middle sheet 28, can space from inner surface of middle sheet 28 of rear cover sheet 22, as shown in FIG. 3, and can be bent hack to the initial position again so that holding sheet 50 and rear cover sheet 22 he parallel on top of each other. Also, folding member 30, middle sheet 28, and exterior sheet 32 can be configured such that they do not bend to the other direction, the direction in which middle sheet 28 of rear cover sheet 22 would push against holding sheet 50. This arrangement could help to avoid that electronic device 60 would be pushed out from holding sheet 50. Moreover, holding sheet 50 is attached to the exterior sheet 32 of rear cover sheet 22 with the thread 58. In the embodiment shown, thread 58 leads at a certain distance from outer edge of the part of holding sheet 50 that is located over the exterior sheet 32, and is thereby securely attached to exterior Sheet 32. In a variant, holding sheet 50 can be attached to exterior sheet 32 in many different ways, for example, but not limited to, adhesive glue, staples, rivets, and plastic welding.

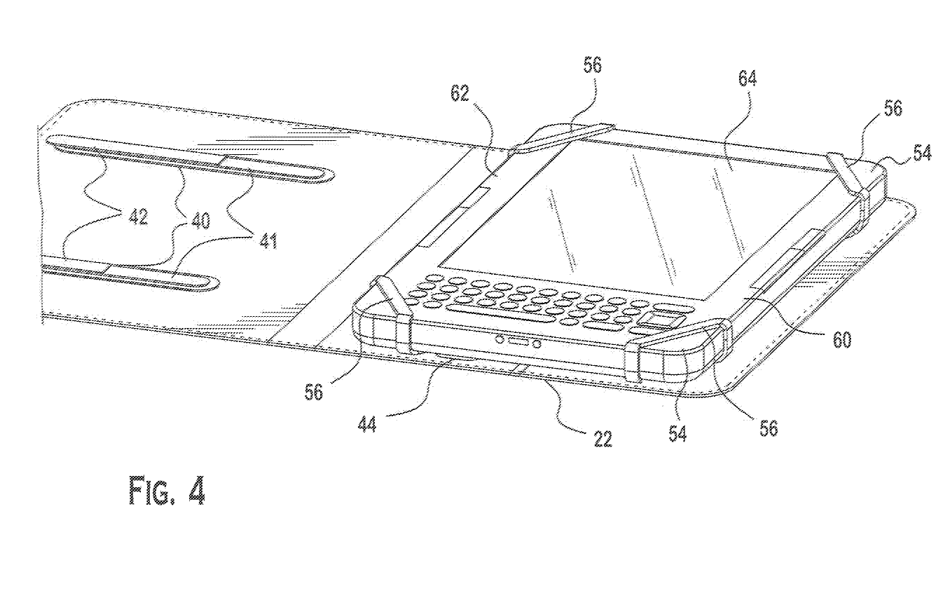

In the variant shown, holding sheet 50 is made of one piece of flexible and elastic rubber-like material having a thickness that is preferably in a range of 0.75 mm to 3 mm, for example but not limited to silicone, rubber, urethane, fluoroelastomer, fluorosilicone, ethylene propylene (EPR), that lies planar on the rear cover sheet 22 without any upward protrusions when no electronic device 60 is attached to holding sheet 50. For example, holding sheet 50 can he made of a rubber mat having an upper surface in the z-direction that has anti-slip properties against a back face of an electronic device 60 that is attached to holding sheet 50. For attachment to electronic device 60, holding sheet 50 has openings 54 in all four corners, and with each corner a holding band or strip 52 is formed that is arranged to bulge away from the corners, so that an outer edge of holding band 52 lies beyond side edges of a middle section of the holding sheet 50. Due to the elasticity of holding hands 52, when an electronic device 60 is placed centered onto holding sheet 50, the bands 52 can be pulled over the corners of electronic device 60 to fasten electronic device 60 to holding sheet 50, as shown in FIG. 4. Thereby, lower side 56 of holding bands 52, as referenced to a relaxed position when device 60 is not present, can be turned upside-down to face away from the upper surface of the corner of electronic device 60. Holding hands 52 are designed such that they do not reach into a screen 64 of electronic device 60, so that viewing and touch-screen operation is not obstructed. Holding sheet 50 with the holding bands 52 can be made of a single sheet and by cutting out four openings 54 in the corners, and by also cutting away side sections of holding sheet 50 between the holding bands 52. When holding bands 52 are attached to device 60, a left side wall 62 of electronic device 60 is not covered by holding sheet 50.

Once electronic device 60 is released from holding sheet 50 by manually pulling holding strips 52 over the corners of electronic device 60, holding sheet 50 goes hack to the planar shape that lies on top of upper surface of rear cover sheet 22. This arrangement and design of the holding sheet 50 allows keeping the thickness T of cover 10 in a z-direction smaller than conventional covers that have holding clips made of hard plastic, or stiff leather, or similar arrangements that protrude in the z-direction away from rear cover sheet 22. This also allows to provide a protective cover 10 having a very low profile when electronic device 60 is removed. Also, the simple, one-piece designs of the holding sheet 50 allow reducing the number of components used to make a holding bracket for an electronic device, thereby reducing complexity of the design that usually relies on multiple attachment bands and holding clips, and lowering its cost. In addition, the design only needs one attachment thread 58 or adhesive material to attach sheet 50 to rear cover sheet 22, so that the design is reliable and durable. Also, compared to conventional protective covers, the holding sheet 50 can be easily replaced if it tears. In a variant, it is also possible that holding sheet 50 is removably attached to exterior sheet 32 by, for example but not limited to a hook and loop fastener, for easy replacement.

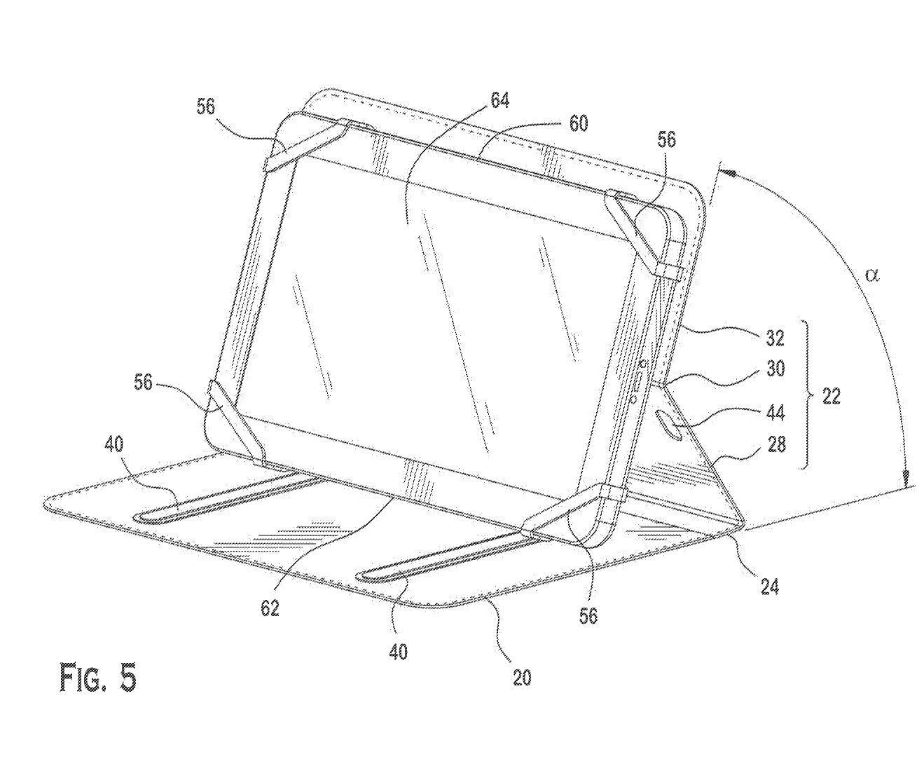

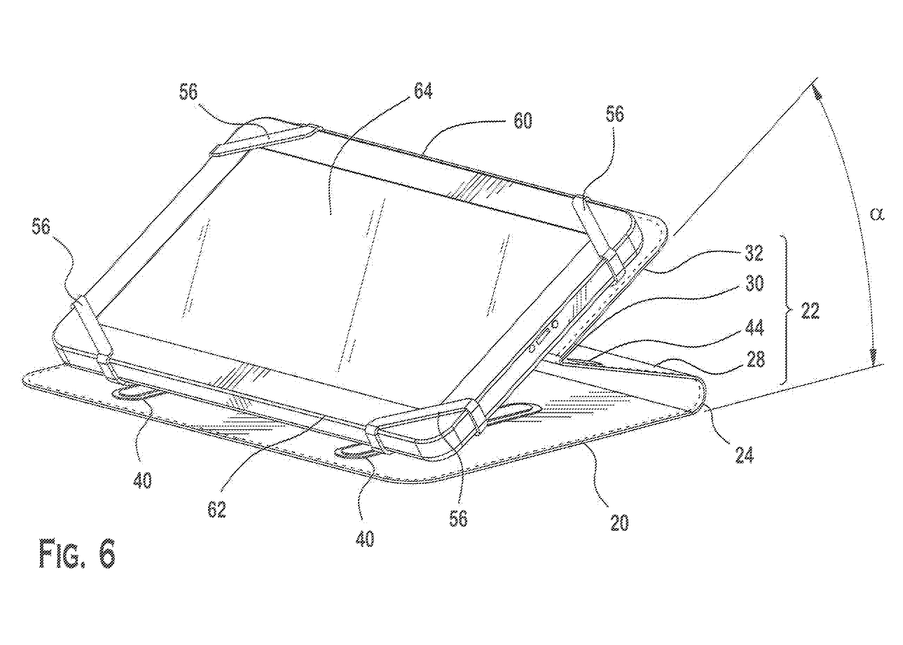

Also, the inner side of front cover sheet 20 has one or more holding tabs or pads 40 that are arranged perpendicularly to a longitudinal extension of the articulable back portion 24, offset from the left side edge of front cover sheet 20 by a distance O, and having a length L. Holding tabs 40 are configured to hold the electronic device 60 in an upright position when electronic device 60 is attached to holding sheet 50, so that a user can put the protective casing 10 on a desk or other surface for reading, the protective casing 10 serving as a stand allowing multiple stand angles, as shown in FIGS. 5-6. In the embodiment shown in FIGS. 1-6, there are two holding tabs 40 that extend over 70% of the inner side of front cover sheet 20. Holding tabs 40 are attached to the inner side of front cover sheet 20 by an adhesive, thread, or other suitable attachment means, and have an upper surface 41 with anti-slip properties, for example holding tabs 40 are made of a rubber-like material that has an upper surface 41 with microscopic pores that act as suction cups on side edge 62 of electronic device 60, or has another type of surface having a coefficient of friction that is sufficient to prevent electronic device 60 from slipping when the side edge 62 of electronic device 60 is placed onto holding tabs 40. Alternatively, upper surface 41 can be made of a roughened surface, for example dented, embossed, sand-paper like, or by another type of surface that improves friction resistance to side edge 62 of electronic device in a direction along the longitudinal axis of the holding tabs 40. In addition, in a variant, tabs 40 do not have a longitudinal shape, but the entire inner surface or a part of the inner surface is formed to have anti-slip properties to hold electronic device 60 at a desired position, for example by using an embossed rubber surface on the inner side of front cover sheet 20.

With electronic device 60 attached to holding sheet 50, the left side edge 62 of electronic device 60 can be put onto the upper surface 41 of holding tabs 40, by opening protective cover 10 by unfolding front and back cover sheets 20, 22 via articulable back portion 24, and by bending folding member 30 so that side edge 62 of electronic device 60 moves away from articulable back portion 24, and can be posed onto tabs 40. Protective cover 10 can then he placed onto the front surface of front cover sheet 20 on a flat surface like a table, sofa, desk, so that a user can view screen 64 of electronic device 60 at a stand angle α, for example an angle α of about 75, as shown in FIG. 5. Upper surface 41 of tabs 40 have anti-slip properties that are configured such that electronic device 60 rests in its upright angled stand position when side edge 62 is positioned onto tabs 40. FIG. 6 shows electronic device 60 attached to holding sheet 50 in which side edge 62 is located close to the outer edges of tabs 40, having a stand angle a of about 30°. Tabs 40 are designed both in length and position as well as with upper surface 41 having a coefficient of friction such that a wide range of stand angles for electronic device 60 is possible, ranging from approximately 30° to 80°, without the need to attach side edge 62 or other parts of electronic device 60 or rear side cover 22 with other means. Also, in a case where tabs 40 are made of a very sticky material, they can be covered with a protective sheet or cover 42 to avoid accumulation of dust when side edge 62 of device 60 is not posed on tabs 40.

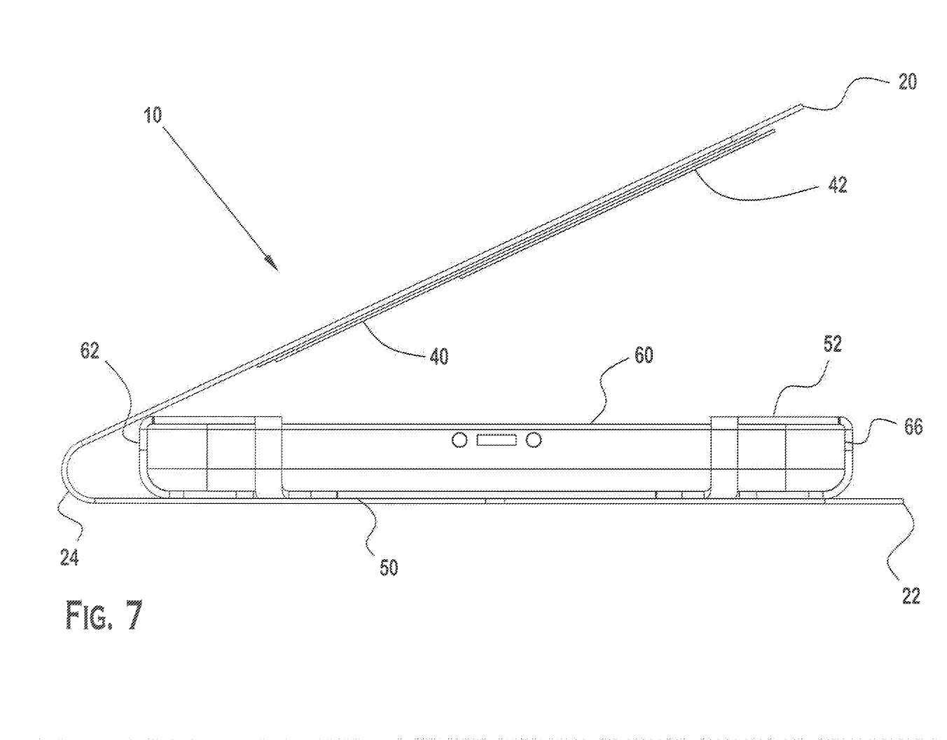

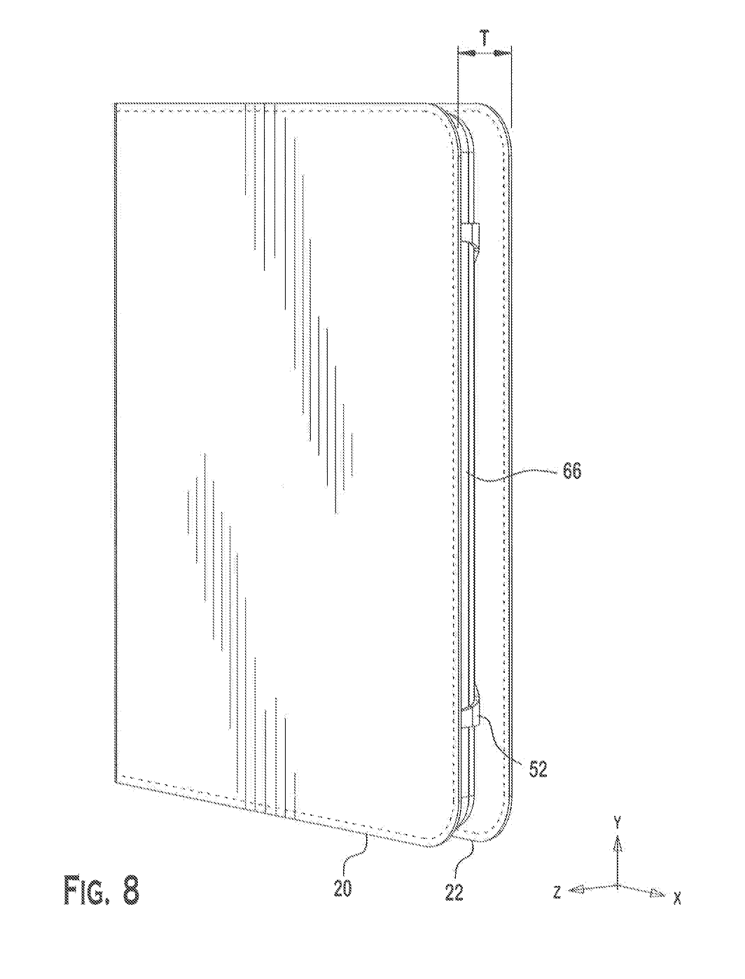

FIG. 7 depicts a side plan view in the y-direction, showing electronic device 60 that is attached to bad cover sheet 22 via the holding sheet 50, with holding strips 52. While the articulable back portion 24 wraps around side edge 62 of device 60, side edges of front and rear cover sheets 20, 22 are made to protrude beyond right side edge 66 of device 60 for protection. FIG. 8 shows the protective cover 10 in a closed state, with electronic device 60 being attached to holding sheet 50. The front and rear cover sheets 20, 22 are designed such that they cover electronic device 60 entirely and are therefore higher and wider in x and y-direction as the electronic device 60, to assure protection against side impacts if protective case 10 and device 60 falls to the ground or is otherwise subjected to lateral shocks. Also, holding hands 52 can be located inside a space that is formed by the closed front and rear cover sheets 20, 22, so that holding strips 52 are also protected from wear and tear.

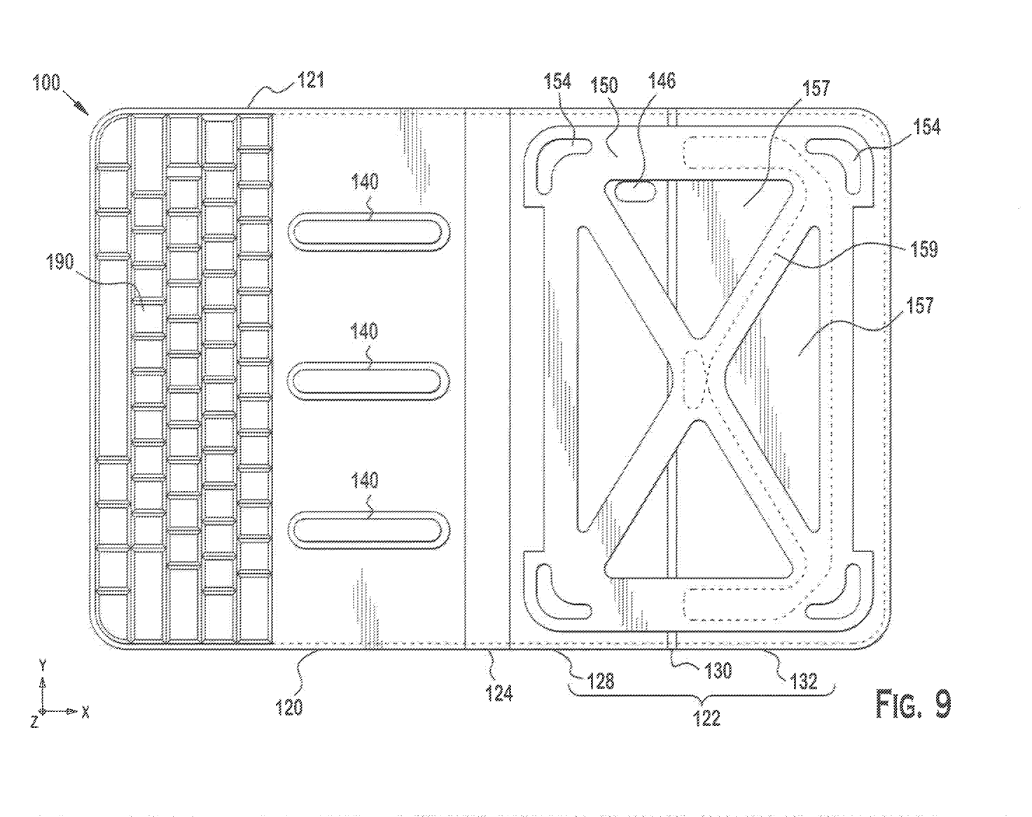

FIG. 9 shows another embodiment of the protective casing 100, with shorter tabs 140 that are accommodated in the right side of the front cover sheet 120, so that the left side 121 of the cover sheet 120 can accommodate a keyboard 190 for operating an electronic device (not shown). Also, three different tabs 140 are shown, with one arranged substantially in the center as seen from a y-direction. In this embodiment, the range of stand angle et is smaller, since tabs 140 are shorter and are not positioned over keyboard 190, preferably in a range of 60° to 80°. Keyboard 190 can be designed to be very flat in the z-direction so that the protective casing 100 adds none or only slightly more to the thickness T than without a keyboard 190, preferably a foil or membrane keyboard, capacitive button keyboard, or other suitable flat keyboard technology. In addition, left side 121 of cover sheet 120 can also simply be a display surface for displaying a virtual keyboard or a projection keyboard by the electronic device. Preferably, keyboard 190 is configured to communicate wirelessly to the electronic device, for example but not limited to a Bluetooth™ or infrared communication interface. Also, in this embodiment, folding member 130 splits rear cover sheet 132 into two sections of different sizes, with middle sheet 128 being smaller than exterior sheet 132.

Moreover, FIG. 9 also shows a variant of flexible and elastic holding sheet 150 having a cross-shaped middle section 159 that is formed by cutting out four triangular cut-out sections 157, to reduce weight and material costs of holding sheet 150. Holding sheet 150 is still formed from a single piece of sheet-like material. Also, cut-out sections 157 can be located at positions in which other electronic elements are located in electronic device, such as but not limited to speakers, microphones, sensors, flashlights, camera lenses, connectors, and a corresponding opening 146 can be provided in back cover sheet 122. Thereby, the other electronic elements will not be obstructed by protective casing 100. Because fastening an electronic device to holding sheet 150 requires pulling comers of sheet 150 having openings 154 in a direction away from a center of sheet 150, in this embodiment, the cross-shaped middle section 159 is configured to reinforce the sheet 150 and to limit the flexibility and/or elasticity to a desired value.

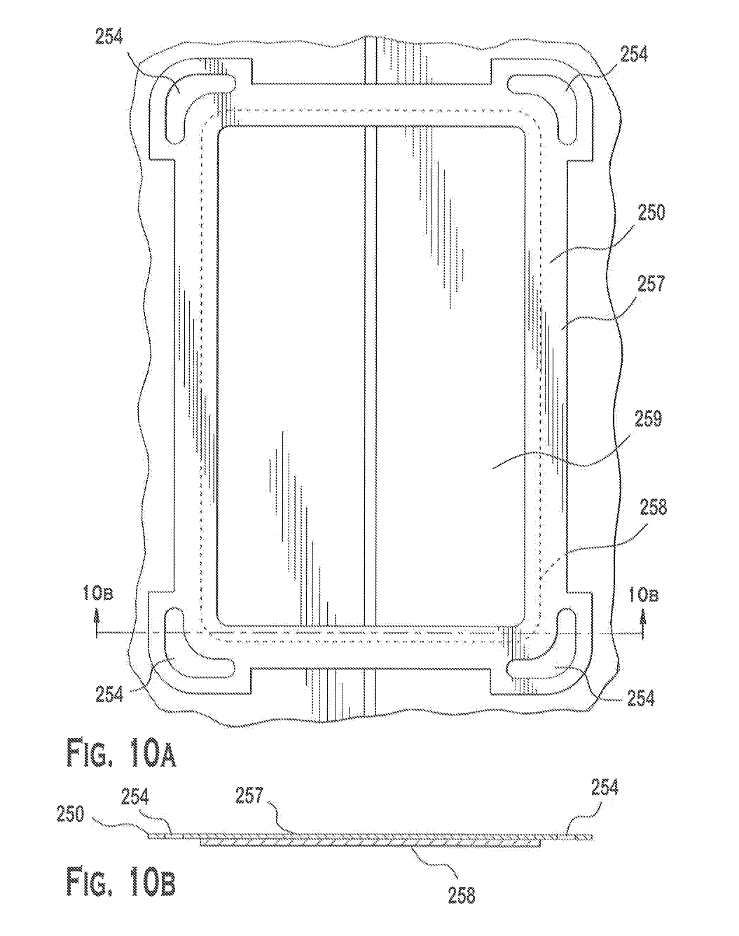

Another embodiment of the holding sheet 250 is shown with respect to FIGS. 10A and 10B, showing a top view of sheet 250, and a cross-sectional view of sheet 250 along lines 10B-10B that is shown in. FIG. 10A. Sheet 250 is made of two different layers 257, 258, having a stiff and thin base frame 258, and an elastic sheet 257 out of which attachment openings 254 are cut into. Because sheet 250 is stiffened and reinforced by the presence of base frame 258, the inner section 259 of attachment sheet 250 can he entirely cut out. This embodiment is useful in situations Where the back side of electronic device is equipped with electronic elements covering a larger surface, for example larger speakers, etc.

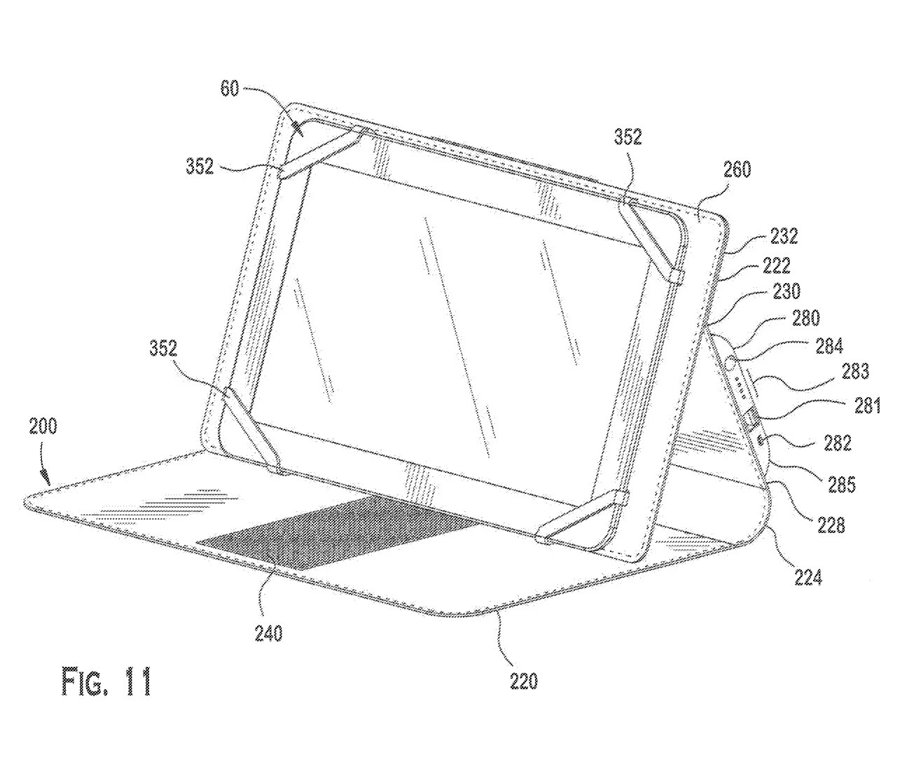

FIGS. 11-15 show another embodiment of a protective cover 200. The protective cover 200 includes a front cover sheet 220 that is attached via an articulable, pivotable, or foldable back portion 224, or spine portion, to a rear cover sheet 222. The articulable back portion 224 is arranged such that the front cover sheet 220 and rear cover sheet 222 can he folded relative to each other to close the protective cover 200 to contain electronic device 60. In a closed state, the inner surfaces of front cover sheet 220 and rear cover sheet 222 face each other and can sandwich an electronic device 60 between each other, the front cover sheet 220 and the rear cover sheet 222 arranged substantially parallel to each other. In an open state, the display of electronic device 60 is exposed, and front cover sheet 220 can be opened at various angles towards rear cover sheet 222. In addition, the rear cover sheet 222 is also configured to be foldable separately from the folding of sheets 220, 222 relative to each other, and for this purpose rear cover sheet 222 is composed of a middle sheet 228 and an exterior sheet 232 that are connected to each other via folding member 230 (e.g., a hinge).

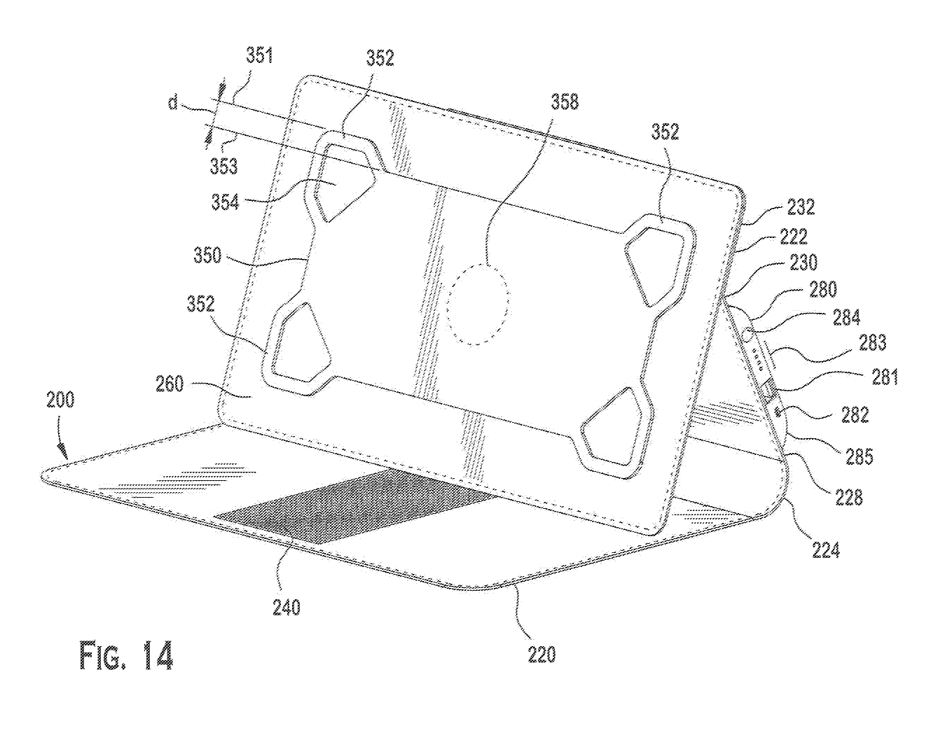

As shown in FIG. 14, a rigid backing sheet 260 is attached to the exterior sheet 232 of the rear cover sheet 222, but is not attached to the middle sheet 228 of the rear cover sheet 222. A holding sheet 350 that is configured to secure the electronic device 60 is attached to the backing sheet 260 by an attachment 358. Holding sheet 350 is configured such that it serves as a mounting bracket to hold electronic device 60 removably to protective cover 200. In the embodiment shown, attachment 358 securing the holding sheet 350 to the backing sheet 260 is located approximately at the center of holding sheet 350. In other variants, the attachment 358 could be positioned at other locations where the holding sheet 350 overlaps with the backing sheet 260. Holding sheet 350 can be attached to backing sheet 260 in many different ways, for example, but not limited to, a thread, adhesive glue, staples, rivets, and plastic welding.

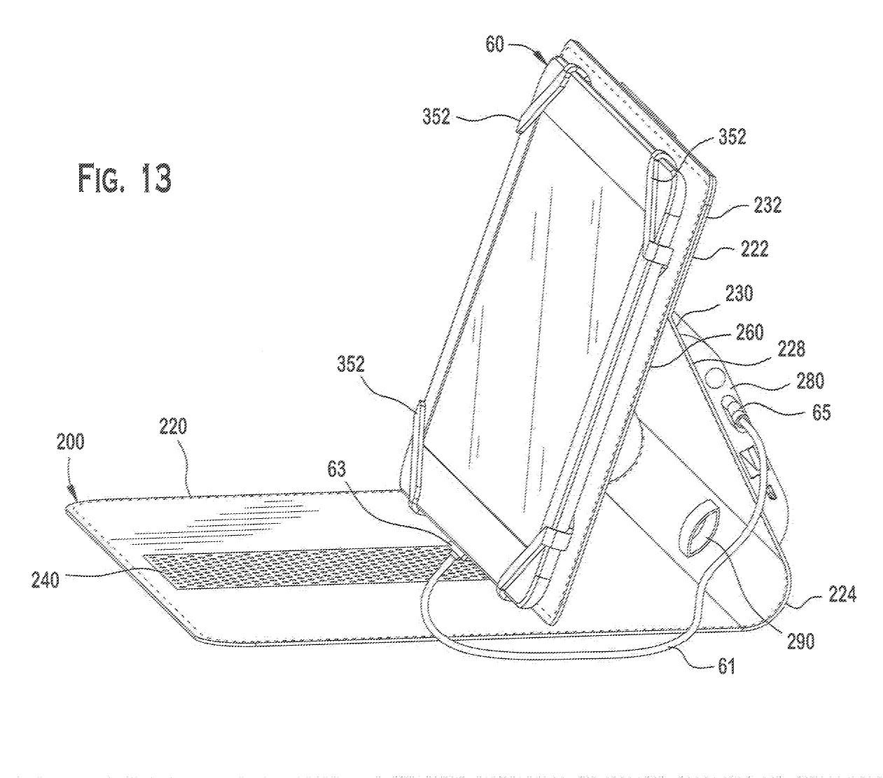

The folding member 230 is arranged in a way that rear cover sheet 222 can be bent such that the left side of backing sheet 260, the part of backing sheet 260 that is not attached to the inner surface of middle sheet 228, can space from inner surface of middle sheet 228 of rear cover sheet 222, as shown in FIG. 13, and can be bent back to the initial position again so that backing sheet 260 and rear cover sheet 222 lie parallel on top of each other. Also, folding member 230, middle sheet 228, and exterior sheet 232 can he configured such that they do not bend to the other direction, the direction in which middle sheet 228 of rear cover sheet 222 would push against backing sheet 260. This arrangement could help to avoid that electronic device 60 would be pushed out from holding sheet 350 and backing sheet 260.

In the embodiment shown, folding member 230 splits rear cover sheet 222 into two parts, the middle sheet 228 and the exterior sheet 232, such that the middle sheet 228 has a larger extension in the width extension (i.e., transverse direction) of the cover 200 than the exterior sheet 232. The width extension of the middle Sheet 228 can be defined by a battery 280 provided on the middle sheet 228. Thus, depending on the size of battery 280, the width extension of middle sheet 228 may vary. Alternatively, the battery 280 may be provided on the exterior sheet 232 of the cover 200, in which case the width extension of the exterior sheet 232 may he greater than the width extension of the middle sheet 228.

Holding sheet 350 may be constructed similar to the embodiments discussed above. According to the embodiment shown in FIG. 14, the holding sheet 350 is provided with openings 354 formed in all four corners of the holding sheet 350, the outer edge of each opening 354 creating a holding band 352. The openings 354 have a pentagonal shape, but could take other shapes as well. The bands 352 extend away from the center of the holding sheet 350 such that an outer periphery 351 of the bands 352 are offset a distance d from an edge 353 of the holding sheet 350. Accordingly, the bands 352 of the holding sheet 350 have a significant amount of elasticity such that when an electronic device 60 is placed centered onto holding sheet 350, the hands 352 can be easily pulled over the corners of electronic device 60 to fasten electronic device 60 to holding sheet 350, as shown in FIGS. 11-13. Furthermore, the improved elasticity of the bands 352 allows for greater compatibility with various types of electronic devices 60.

The inner side of front cover sheet 220 is provided with a holding tab or pad 240 extending in the width extension of the protective cover 200. Holding pad 240 is configured to hold the electronic device 60 in an upright position when electronic device 60 is attached to holding sheet 350, so that a user can put the protective cover 200 on a desk or other surface for reading, the protective cover 200 serving as a stand allowing multiple stand angles. Holding pad 240 is attached to the inner side of front cover sheet 220 by an adhesive, thread, or other suitable attachment means, and has an upper surface with anti-slip properties. For example, holding pad 240 may be made of a rubber-like material that has an upper surface with microscopic pores that act as suction cups on a side edge of backing sheet 260, or has another type of surface having a coefficient of friction that is sufficient to prevent backing sheet 260 from slipping when the side edge of backing sheet 260 is placed onto holding pad 240. Alternatively, the upper surface of holding pad 240 can be made of a roughened surface, for example dented, embossed, sand-paper like, or by another type of surface that improves friction resistance to the side edge of hacking sheet 260 in the width extension direction of the protective cover 200. In addition, in a variant, holding pad 240 does not have an elongated shape, but the entire inner surface or a part of the inner surface of the front cover sheet 220 has anti-slip properties to hold electronic device 60 at a desired position, for example by using an embossed rubber surface on the inner side of front cover sheet 220.

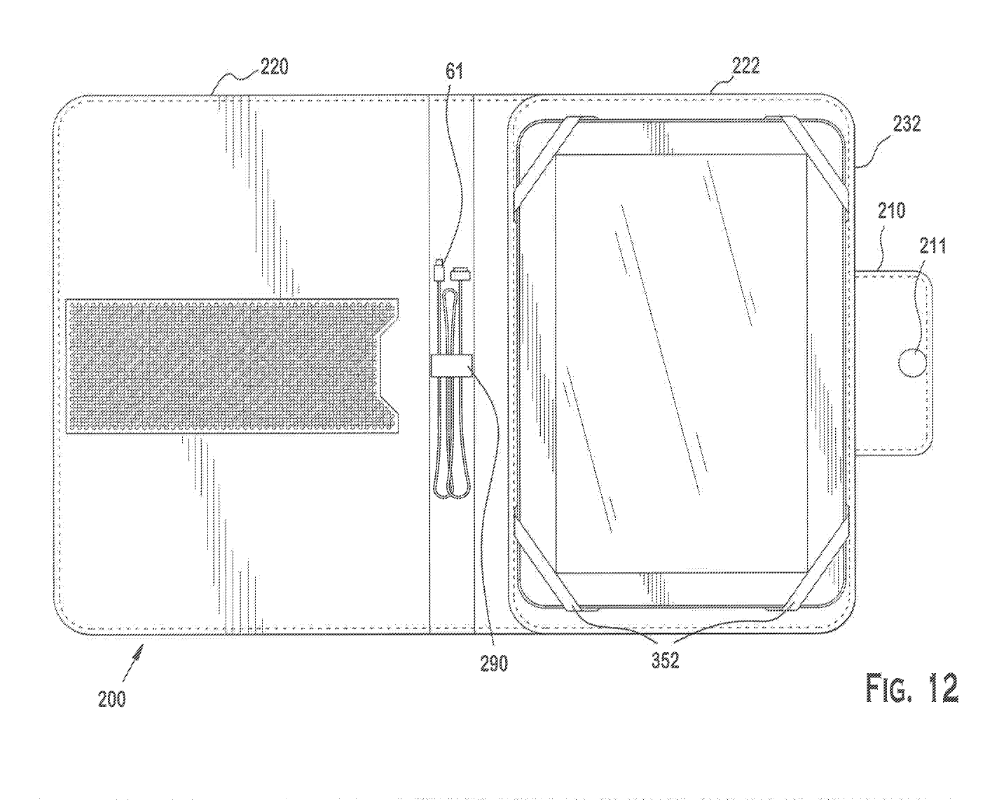

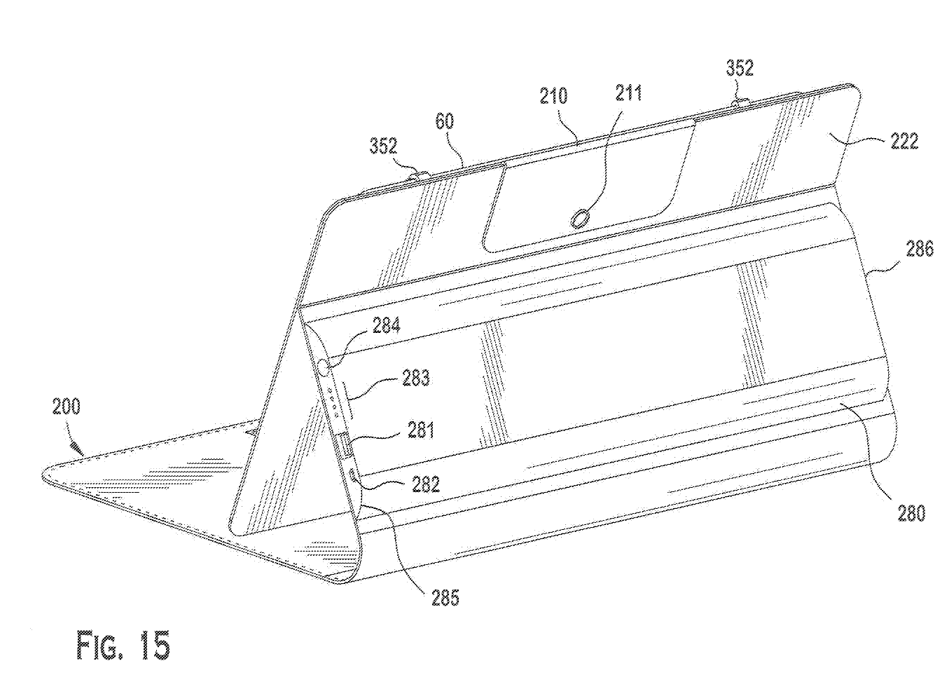

At least one of the front cover sheet 220 and the rear cover sheet 222 can also be equipped with a mechanism to hold the front and rear cover sheets 220, 222 together in a closed state, for example but not limited to an elastic band, a hook and loop fastening strap, a zipper, magnetic strap, buckle, clip-on band, and push-button band laces. As shown in FIGS. 12 and 15, a flap 210 is attached to the exterior sheet 232 of the rear cover sheet 222 at a transverse end of the protective cover 200. The flap 210 includes a magnet 211 that is configured to interact with a corresponding magnet (not shown) in the front cover sheet 220 to thereby secure the protective cover 200 in a dosed position. As shown in FIG. 15, the magnet 211 in the flap 210 could also interact with a corresponding magnet (not shown) in the rear cover sheet 222 to secure the flap 210 when the protective cover 200 is in the open state.

The protective cover 200 is also provided with a battery 280 to serve as a source of power for the electronic device 60. Preferably, the battery 280 has approximately the same capacity as the battery of the electronic device 60, thereby providing up to one additional full charge for the device 60. According to the embodiments shown in FIGS. 11-17, the battery 280 is preferably attached to the outer surface of the middle sheet 228 of the rear cover sheet 222, Positioning the battery 280 on the outer surface of the middle sheet 228 provides the protective cover 200 with a low and sturdy center of gravity, thereby providing stability to the protective cover 200 when in use and while the device 60 is being charged. Moreover, providing the battery 280 on the outer surface of the middle sheet 228 provides for a compact cover 200 in the closed condition. Additionally, the risk that the battery 280 will damage the device 60 or that the battery 280 will interfere with the device's 60 sensors and antennas is minimized. In this regard, additional shielding (not shown) may be provided in the middle sheet 228 to further protect the device 60. Furthermore, if the battery 280 were located in the front cover sheet 220, the battery 280 would be positioned adjacent to a supporting surface (e.g., a desk or table) when in use. Accordingly, heat transfer away from the battery 280 could be inhibited. Positioning the battery 280 on the outer surface of the middle sheet 228 results in improved airflow about the battery 280, and, consequently, improved heat transfer away from the battery 280.

The battery 280 may be formed as an integral part of the middle sheet 228. The battery 280 could be sewn into the material of the middle sheet 228 or otherwise fixedly attached to the middle sheet 228, for example, by an adhesive. Alternatively, the battery 280 could be removably attached to the middle sheet 228, thereby allowing the battery 280 to he removed and replaced if necessary. For instance, the battery 280 could be inserted into a pouch (not shown) that is formed of, for example, an elastic material or another tight-fitting material. Such a pouch could also be provided with a fastener, such as a hook and loop fastener, that could be opened to thereby allow the battery 280 to he removed.

Battery 260 includes a device port 281 for accepting a plug 65 from a cable 61 that can be connected to the electronic device 60. Device port 281 of the battery 280 can take several different forms to accept various connectors, including but not limited to, IEEE 1394 interface (FireWire), Universal Serial Bus (USB), or a device 60 specific connector. As shown in FIGS. 12 and 13, the cover 200 is provided with a strap 290 for securing cable 61 when the cable 61 is not being used to connect device 60 to the battery 280. Strap 290 can be, for example, a pouch, an elastic strap, a hook and loop fastening strap, or a strap with a button or other fastening means. The cover 200 may also include a securing device (not shown) on an inner surface of the front cover sheet 220 or the rear cover sheet 222 to secure the cable 61 when the device 60 is connected to the battery 280 by cable 61. The battery 280 also includes a charging port 282 for connecting the battery 280 to a power source for charging the battery 280. Charge indicators 283, such as, for example, light emitting diodes or the like, indicate the amount of charge remaining in the battery 280 when button 284 is pressed to activate the charge indicators 283. The battery 280 may be provided with a mechanism that automatically shuts off the battery 280 when charging of the battery 280 is complete. Battery 280 could also be provided with additional ports capable of accepting various types of connectors to enable the connection of multiple electronic devices to the battery 280 at the same time.

In the embodiment shown, the battery 280 has a first end 285 and second end 286 shown in FIGS. 11 and 15. The first and second ends 285, 286 extend to the longitudinal ends of the cover 200. The first end 285 of the battery 280 includes the above-described device port 281 and is therefore preferably positioned at a longitudinal end of the cover 200, to thereby provide easy access to the device port 281 from the device 60. Depending upon the size of the battery 280, the second end 286 may not extend to a longitudinal end of the cover 200.

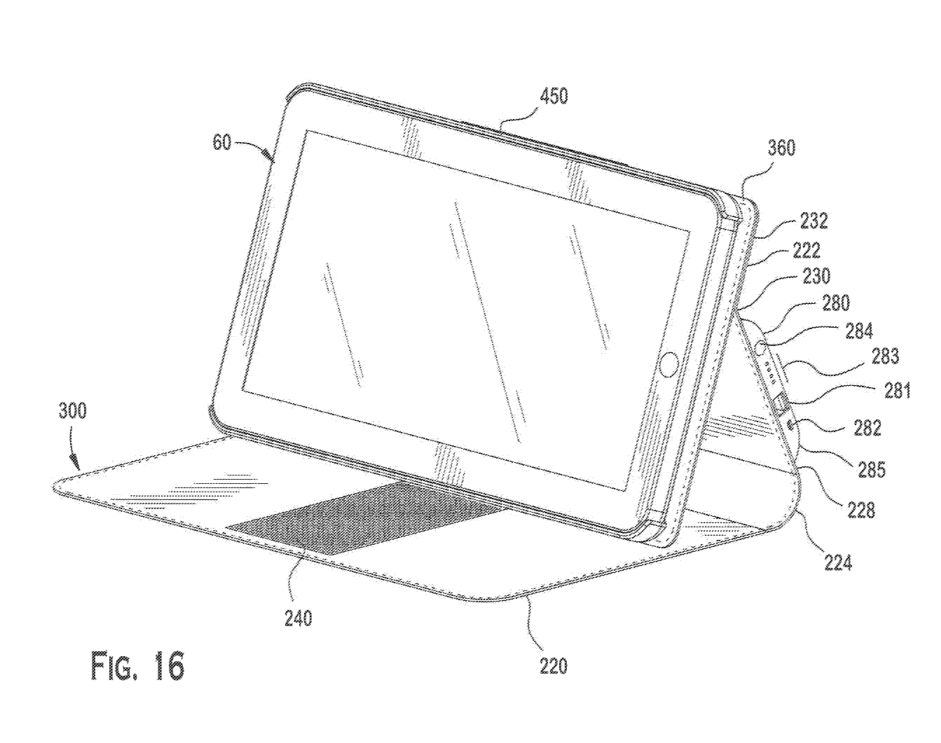

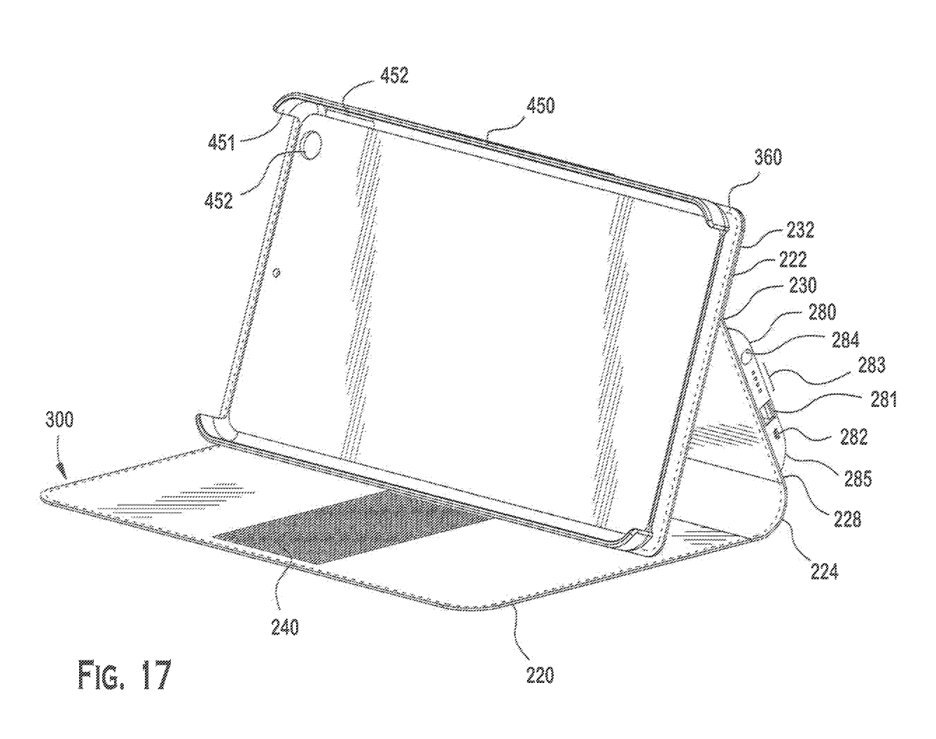

FIGS. 16 and 17 show another embodiment of the protective cover 300. Protective cover 300 is similar to the protective cover 200 shown in FIGS. 11-15, with the holding sheet 350 being replaced by a shell 450 attached to a backing sheet 360. Shell 450 can be formed of a plastic material and secured to the backing sheet 360 by several different methods, including but not limited to a thread, adhesive glue, rivets, and plastic welding. Shell 450 may completely surround all edges of device 60 with openings 452 provided in the shell 450 to accommodate, for example, buttons or connection ports of the device 60. Alternatively, a cut-out section 451 can he formed at portions of the periphery of the shell 450. Device 60 is secured in the shell 450 based on a press fit arrangement between the inner surface of the periphery of the shell 450 and the periphery of device 60. During use, either a surface of the shell 450 or the backing sheet 360 could interact with the holding pad 240 to hold the electronic device 60 in an upright position.

While the invention has been disclosed with reference to certain preferred embodiments, numerous modifications, alterations, and changes to the described embodiments are possible without departing from the sphere and scope of the invention, as defined in the appended claims and their equivalents thereof. Accordingly, it is intended that the invention not be limited to the described embodiments, but that it have the full scope defined by the language of the following claims.

1. A protective cover for an electronic device comprising:
a front cover;
a rear cover including a middle rear cover, an exterior rear cover, and a folding portion that connects the middle rear cover to the exterior rear cover;
an articulable back that connects the rear cover to the front cover;
a holding member that is attached to an inner surface of the exterior rear cover and is not attached to the middle rear cover for securing the electronic device to the protective cover; and
a battery attached to the middle rear cover.

2. The protective cover of claim 1, further comprising:
an anti-slip pad attached to an inner surface of the front cover, wherein the anti-slip pad has an upper surface having a friction coefficient, the friction coefficient maintaining a position of the electronic device secured by the holding member in a configuration Where the exterior rear cover is angled from the middle rear cover at the folding portion such that the holding member is spaced from an inner surface of the middle rear cover, and an edge of the electronic device or an edge of the holding member is positioned onto the anti-slip pad.

3. The protective cover of claim 2, wherein the anti-slip pad is formed as an elongated pad extending substantially perpendicularly to a longitudinal axis formed by the articulable back.

4. The protective cover of claim 1, wherein the holding member is a holding sheet that has openings formed in corners of the holding sheet to form bands, the bands configured to attach to corners of the electronic device.

5. The protective cover of claim 4, wherein the holding sheet is made of a single piece of an elastic material.

6. The protective cover of claim 1, wherein the holding member is a shell configured such that the electronic device is press fit into the shell, thereby securing the electronic device to the protective cover.

7. The protective cover of claim 1, wherein the battery is attached to an outer surface of the middle rear cover.

8. The protective cover of claim 7, wherein when the protective cover is in an open position, the holding member is spaced from an inner surface of the middle rear cover and the battery.

9. The protective cover of claim 7, wherein a transverse extension of the middle rear cover is greater than a transverse extension of the exterior rear cover.

10. The protective cover of claim 9, wherein a transverse extension and a longitudinal extension of the battery are substantially equal to the transverse extension and a longitudinal extension of the middle rear cover.
